(19) United States
(12) Patent Application Publication
(10) Pub. No.: US 2022/0043684 A1
(43) Pub. Date: Feb. 10, 2022

(54) MEMORIES COMPRISING PROCESSOR PROFILES

(71) Applicant: Hewlett-Packard Development Company, L.P., Spring, TX (US)

(72) Inventor: Louis M. Gaiot, Fort Collins, CO (US)

(73) Assignee: Hewlett-Packard Development Company, L.P., Spring, TX (US)

(21) Appl. No.: 17/415,879

(22) PCT Filed: Mar. 7, 2019
(86) PCT No.: PCT/US2019/021184

§ 371 Date: Jun. 18, 2021

(51) Int. Cl. G06F 9/50; G06F 9/4401; G06F 1/08; H03K 19/173

(52) U.S. Cl. CPC G06F 9/5016; G06F 9/5038; H03K 19/1737; G06F 1/08; G06F 9/4403

(57) ABSTRACT

In an example, a memory includes processor profiles to load into a processor. The processor may provide an address to access a processor profile. The address may be modified to select a processor profile to load into the processor.

### BACKGROUND

When starting up, a processor may load a processor profile. The processor profile may include settings for operation of the processor that provides a balance between processing speed, processing power, power draw, and other operational characteristics. The processor may load the processor profile from a particular location in memory.

### BRIEF DESCRIPTION OF THE DRAWINGS

Various examples will be described below referring to the following figures:

FIG. 1 shows a memory coupled to a processor and an address controller in accordance with various examples;

FIG. 2 shows a memory coupled to a processor and an address controller, the address controller to multiplex an address offset onto address lines in accordance with various examples;

FIG. 3 shows two memories coupled to a processor via a selector in accordance with various examples;

FIG. 4 shows a method of selecting a processor profile and loading the processor profile into a processor; and

FIG. 5 shows a method of loading a first processor profile into the processor during a first startup operation and loading a second processor profile into the processor during a second startup operation.

### DETAILED DESCRIPTION

A processor may load a processor profile to configure settings for the processor's operation. A processor may load the processor profile at startup of the processor. The processor may load the processor profile from a specific memory address and not have a built-in option to load a processor profile from a different memory address. A changing workload for the processor, however, might benefit from loading different processor profiles at different points in time. One processor profile may enable the processor to provide higher processing throughput, while another processor profile may provide lower power consumption.

An address controller or selector may be used to load different processor profiles into the processor at different times. The processor may provide the same memory address for loading into the processor, but the address controller or selector may modify the memory access to provide different processor profiles, depending on a configuration setting to load a different processor profile. Changing between different processor profiles may be transparent to the processor.

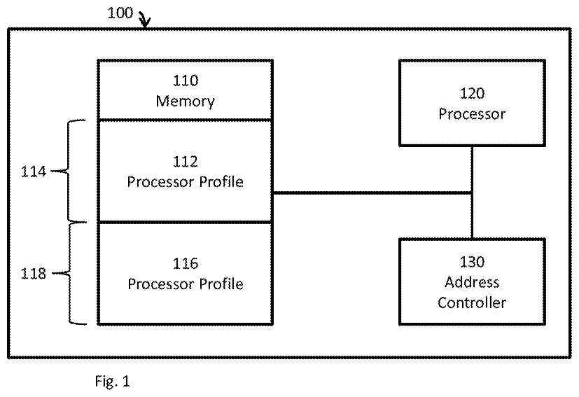

FIG. 1 shows a memory 110 coupled to a processor 120 and an address controller 130 in accordance with various examples. An apparatus 100 includes a memory 110, a processor 120, and an address controller 130. The apparatus 100 may include a computer system, an electronic control system, or a computing device. The memory 110 comprises a first processor profile 112 located at a first memory range 114 and a second processor profile 116 located at a second memory range 118. The memory 110, processor 120, and address controller 130 may be coupled together, such as via a bus.

A processor profile 112, 116 may be loaded into the processor 120 to initialize various settings that control the operating condition boundaries of the processor. The settings may include a clock rate of the processor, a clock rate of a memory bus, a clock rate of graphics memory, a thermal limit, and enabling or disabling parallel processing units. The processor profiles 112, 116 may include microcode for execution by the processor 120 to implement the operating condition boundaries. A processor profile 112, 116 is to be loaded into the processor 120 at startup or initialization of the processor 120 and remains unchanged until the processor 120 is rebooted or initialized again. Additional settings may be changed during operation of the processor 120 as constrained by the processor profile 112, 116. These additional settings may have some overlap with settings of the processor profile 112, 116. For example, a processor profile 112, 116 may initialize a processor to be in a power-saving mode. The processor profile 112, 116 may include a clock rate setting of the processor 120 that sets boundaries on the clock rate of the processor 120 between a minimum clock rate and a maximum clock rate. During operation, the processor 120 may modify the clock rate within the minimum and maximum clock rates specified by the processor profile 112, 116. A different processor profile 112, 116 may specify a different clock rate setting for the processor 120, which corresponds to a different minimum and maximum clock rate range that may be selected during operation of the processor 120. As an example, a clock rate of 1 gigahertz may be settable during operation of the processor 120 when one processor profile 112 is loaded, but not settable during operation of the processor 120 when a different processor profile 116 is loaded. If the processor profile 116 is loaded and the processor is to be set to a clock rate of 1 gigahertz, the processor 120 may be rebooted and reinitialized to load a processor profile 112 that allows setting a 1 gigahertz clock rate during operation of the processor 120.

In various examples, the processor 120 may load a processor profile 112, 116 when initializing the processor. Once initialized, the processor profile 112, 116 may remain in use until the processor 120 is restarted and initialized again. The processor 120 may expect the processor profile 112, 116 to begin at a specific memory address. The processor 120 may read the memory 110 at the memory address to begin loading the processor profile 112, 116. The processor profile 112, 116 may include instructions for the processor 120 to execute while loading the processor profile 112, 116. The processor profile 112, 116 may be a fixed size, or the size may be open ended with the processor 120 continuing to load the processor profile 112, 116 until the processor profile 112, 116 indicates a termination point has been reached.

In various examples, the first processor profile 112 may be a default processor profile for the processor 120. The apparatus 100 may be a laptop computer system. The first processor profile 112 may configure the processor 120 to limit the processor throughput in order to extend the battery life of the apparatus 100. The second processor profile 116 may configure the processor to provide maximum processor throughput without regard to power consumption. The second processor profile 116 may be used when the user is connected to a power outlet and may not be draining the battery or when the user wants increased performance regardless of the drain on the battery. A user may be able to change the apparatus to use the second processor profile 116 by changing a setting prior to rebooting the apparatus 100 or by accessing a boot screen during startup of the apparatus 100. A systems administrator may select the processor profile 112, 116 through remote access calls to the apparatus 100. Data related to the selection of the appropriate processor profile 112, 116 may be stored in a memory or a register that is preserved on restart of the processor 120. The memory or register may be part of the address controller 130. The first processor profile 112 may set a certain thermal limit and a certain clock rate setting for the processor 120. The second processor profile 116 may set a higher thermal limit and a higher clock rate setting for the processor 120.

The processor 120 may comprise a microprocessor, a microcomputer, a microcontroller, a field programmable gate array (FPGA), or discrete logic. The processor 120 may execute machine-readable instructions that implement the methods described herein. The processor 120 may include a central processing unit of a computer system or a graphical processing unit. The memory 110 may include a hard drive, solid state drive (SSD), flash memory, electrically erasable programmable read-only memory (EEPROM), or random access memory (RAM). The address controller 130 may comprise a microprocessor, a microcomputer, a microcontroller, a field programmable gate array (FPGA), or discrete logic. The memory 110 may be a non-transitory medium and not merely an electromagnetic signal.

The address controller 130 may be used to select which processor profile 112, 116 is loaded into the processor 120. The address controller 130 may accomplish this by modifying a read address from the processor 120 to be within the first memory range 114 or within the second memory range 118. In various examples, the address controller 130 may modify the read address on the bus as it is provided from the processor 120 to the memory 110. In various examples, the address controller 130 may receive the read address from the processor, modify the read address, and then pass the read address to the memory 110 as a separate bus transaction.

In various examples, the memory 110 may store the first processor profile 112 and second processor profile 116 at different offsets. The beginning memory address for the memory ranges 114, 118 may share the same lower bits, but have different upper bits. For example, the first processor profile 112 may start at memory address 0x0000. The second processor profile 116 may start at memory address 0x1000. Additional processor profiles may be located starting at other increments of the upper bits, e.g., 0x2000 and 0x3000. In such a configuration, the address controller 130 may alter the upper bits of the read address and leave the lower bits unaltered. If the first processor profile 112 does not consume the full memory range 114 between 0x0000 and 0x0FFF, those memory addresses may be used to store other information. The number of bits used to address the memory may vary. For example, some memories may be addressed using 8 bits, others 64 bits.

In various examples, the addresses to access the first memory range 114 and the second memory range 118 may use other offsets. The address controller 130 may modify the read address from the processor 120 by adding a specific offset to the read address. For example, the first memory range 114 may start at 0x0000 and the second memory range 118 at 0x05B2. If the second processor profile 116 is to be loaded, the address controller 130 may add 0x05B2 to the read address provided by the processor 120 to place the memory read into the second memory range 118. The processor 120 may thus attempt to read the different processor profiles 112, 116 from the same memory location, with the address controller 130 handling the selection between the specific processor profiles 112, 116.

In various examples, additional logic may be present to access the memory 110 or load the processor profiles 112, 116 into the processor 120. The additional logic may be in the form of a processor or peripheral logic.

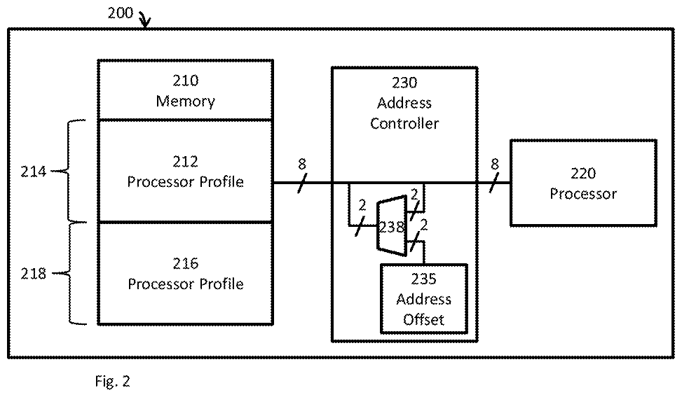

FIG. 2 shows a memory 210 coupled to a processor 220 and an address controller 230, the address controller 230 to multiplex an address offset 235 onto address lines in accordance with various examples. Apparatus 200 includes a memory 210, a processor 220, and an address controller 230. The memory 210, processor 220, and address controller 230 are coupled together, such as via a bus. As depicted in FIG. 2, the bus may include eight lines for an address. Additional lines may be included for data or the data lines may be multiplexed with the address lines. Memory 210 includes a first processor profile 212 at a first memory range 214. Memory 210 includes a second processor profile 216 at a second memory range 218. Address controller 230 includes a multiplexor 238 and an address offset 235.

The multiplexor 238 may be to modify an address provided by the processor 220. For example, the address to access the memory 210 may be an 8-bit address. To select between the first memory range 214 and the second memory range 218 may involve modifying the upper two bits, without changing the lower six bits. The first memory range 214 may start at 0x00, while the second memory range 218 may start at 0x80. The address offset 235 may be the bit values 0b01 to modify the upper two address bits when the second memory range 218 is to be accessed.

In various examples, an adder may be used to add the eight bits of address with an eight bit offset, where manipulation of the address involves more than just changing the upper address bits. The adder may add the address offset 235 to the address, with that output provided to the multiplexor 238. The multiplexor 238 may operate on the eight address lines of the bus, not just two address lines.

In various examples, the address and data may be multiplexed over the same lines of the bus. The address controller 230 may change the multiplexor 238 selection for the data phase of the memory read, so the data is provided over the bus to the processor 220.

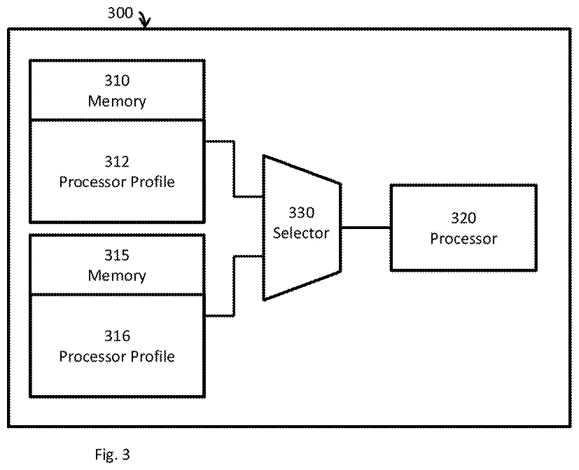

FIG. 3 shows two memories 310, 315 coupled to a processor 320 via a selector 330 in accordance with various examples. Apparatus 300 includes a first memory 310, a second memory 315, a processor 320, and a selector 330. The first memory 310 includes a first processor profile 312. The second memory 315 includes a second processor profile 316.

The selector 330 may include a multiplexor. The selector may selectively couple the first memory 310 or the second memory 315 to the processor 320 to select the processor profile 312, 316 to load into the processor 320.

In various examples, the selector 330 may include a multiplexor to multiplex address and data lines, routing them from the processor 320 to the first memory 310 or the second memory 315. The processor 320 may provide a read address to the selected memory, which may provide the selected processor profile to the processor 320. The non-selected memory may not receive the read command.

In various examples, the selector 330 may utilize enable pins to select between the first memory 310 and the second memory 315. When the first processor profile 312 is to be loaded, the selector 330 may enable the first memory 310 and disable the second memory 315. The second memory 315 may place its connection to the bus in a high impedance state while disabled. When the second processor profile 316 is to be loaded, the selector 330 may disable the first memory 310 and enable the second memory 315. The first memory 310 may place its connection to the bus in a high impedance state while disabled.

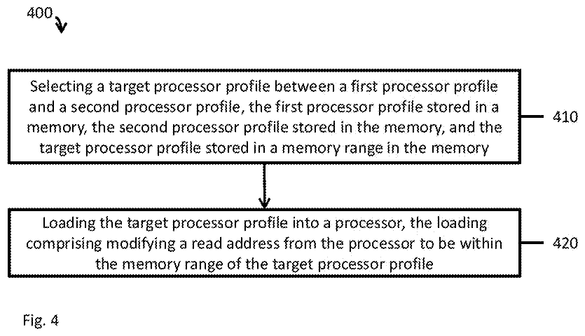

FIG. 4 shows a method 400 of selecting a processor profile and loading the processor profile into a processor. The method 400 includes selecting a target processor profile between a first processor profile and a second processor profile, the first processor profile stored in a memory, the second processor profile stored in the memory, and the target processor profile stored in a memory range in the memory (410). The method 400 includes loading the target processor profile into a processor, the loading comprising modifying a read address from the processor to be within the memory range of the target processor profile (420).

In various examples, the selecting a target processor profile may include providing a configuration interface for a user to select between the first processor profile and the second processor profile. Additional processor profiles may be made available. The configuration interface may allow a user to modify a processor profile or save a set of configurations as a new processor profile that may be selected. The configuration interface may be displayed during startup of the processor, such as during a power-on self-test (POST) operation or if a user enters a startup configuration mode, such as may be provided by a basic input/output system (BIOS), extensible framework interface (EFI), unified extensible framework interface (UEFI), or comparable startup configuration screen. The configuration interface may be displayed by an application that may be executed by the processor after startup. The configuration interface may allow a user to select a processor profile to use after rebooting the processor. A systems administrator may be able to remotely access a computer system including the processor and modify a configuration file that is referenced to select the processor profile to load into the processor profile on startup. Loading of the processor profile into the processor may not take place until the processor is rebooted.

In various examples, a user may select a target processor profile to load into the processor during startup of a computer system that includes the processor. The startup may include execution of a BIOS. During execution of a POST by the BIOS, the user may be able to enter a configuration screen, such as by hitting the Delete key at a certain time during startup. The BIOS may display various configuration screens to change settings of the computer system. The configuration screens may provide the user with the ability to select between different processor profiles to load into the processor during startup. Once the user has selected a processor profile and instructed the BIOS to continue starting up the computer system, the BIOS may instruct the processor and an address controller to load the target processor profile into the processor. At startup and before execution of the BIOS, the processor may not have a processor profile loaded. Loading the processor profile may be one of the tasks the BIOS is to perform. Before the BIOS turns over control of the processor to the operating system, the processor profile may be loaded. The processor profile may not be modified or switched with another processor profile without restarting or reinitializing the processor, at which point the BIOS may load a different processor profile.

In various examples, the processor may be part of a computer system. The user may be able to execute an application on the computer system during normal operation of the computer system. The application may allow the user to select a target processor profile to load into the processor during the next startup or reboot of the computer system. A setting specifying the target processor profile may be stored in non-volatile memory and specify the processor profile to load into the processor. Such a setting may be modified remotely, such as by a systems administrator using a network management tool.

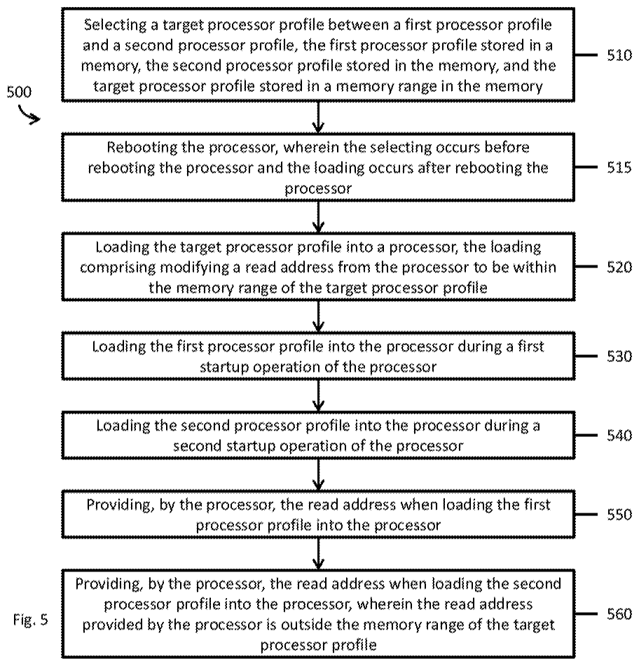

FIG. 5 shows a method 500 of loading a first processor profile into the processor during a first startup operation and loading a second processor profile into the processor during a second startup operation. The method 500 includes selecting a target processor profile between a first processor profile and a second processor profile, the first processor profile stored in a memory, the second processor profile stored in the memory, and the target processor profile stored in a memory range in the memory (510). The method 500 includes rebooting the processor, wherein the selecting occurs before rebooting the processor and the loading occurs after rebooting the processor (515). The method 500 includes loading the target processor profile into a processor, the loading comprising modifying a read address from the processor to be within the memory range of the target processor profile (520). The method 500 includes loading the first processor profile into the processor during a first startup operation of the processor (530). The method 500 includes loading the second processor profile into the processor during a second startup operation of the processor (540). The method 500 includes providing, by the processor, the read address when loading the first processor profile into the processor (550). The method 500 includes providing, by the processor, the read address when loading the second processor profile into the processor, wherein the read address provided by the processor is outside the memory range of the target processor profile (560).

In various examples, the selecting a target processor profile between a first processor profile and a second processor profile may include selection of the first processor profile. The loading the target processor profile may be in response to selecting the target processor profile. The loading the target processor profile into a processor may include loading the first processor profile into the processor. Between the loading the first processor profile into the processor and the loading the second processor profile into the processor, the second processor profile may be selected to be loaded into the processor. The loading the second processor profile into the processor during a second startup operation of the processor may be in response to selecting the second processor profile to be loaded into the processor. When rebooting or starting up the processor, the processor may change between the loading the first processor profile, the second processor profile, or additional processor profiles.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. An apparatus comprising:
a processor;
a memory coupled to the processor, the memory comprising a first processor profile at a first memory range and a second processor profile at a second memory range;
a bus coupled to the memory and the processor, the processor to provide a read address to the bus; and
an address controller coupled to the bus, the address controller to modify the read address to a modified read address, the modified read address being in the first memory range or the second memory range, the address controller to provide the modified read address to the memory, the processor to load the first processor profile or the second processor profile based on the modified read address.

2. The apparatus of claim 1, wherein the processor is to load the first processor profile into the processor at a startup time of the processor based on the modified read address being in the first memory range.

3. The apparatus of claim 1, wherein the first processor profile comprises a first value for a clock rate setting, the second processor profile comprises a second value for the clock rate setting, and the first value is different than the second value.

4. The apparatus of claim 1, wherein the address controller comprises a multiplexer, the multiplexer coupled to the processor and the memory, and the multiplexer to select an address offset for the modified read address.

5. The apparatus of claim 1, wherein the processor includes a graphical processing unit.

6. An apparatus comprising:
a processor;
a first memory coupled to the processor, the first memory comprising a first processor profile to be loaded into the processor;
a second memory coupled to the processor, the second memory comprising a second processor profile to be loaded into the processor; and
a selector to select between the first memory and the second memory during a startup time of the processor.

7. The apparatus of claim 6, the selector comprising a multiplexer coupled to a first data line of the first memory, a second data line of the second memory, and the processor.

8. The apparatus of claim 6, wherein the first processor profile includes a first thermal limit, the second processor profile includes a second thermal limit, and the first thermal limit is different than the second thermal limit.

9. The apparatus of claim 6, wherein the first processor profile is located at a memory address value in the first memory, and the second processor profile is located at the memory address value in the second memory.

10. The apparatus of claim 6, wherein the selection by the selector is based on an input from a user during the startup time of the processor.

11. A method comprising:
selecting a target processor profile between a first processor profile and a second processor profile, the first processor profile stored in a memory, the second processor profile stored in the memory, and the target processor profile stored in a memory range in the memory; and
loading the target processor profile into a processor, the loading comprising modifying a read address from the processor to be within the memory range of the target processor profile.

12. The method of claim 11, wherein the first processor profile includes a clock rate setting of the processor.

13. The method of claim 11 comprising rebooting the processor, wherein the selecting occurs before rebooting the processor and the loading occurs after rebooting the processor.

14. The method of claim 11 comprising:
loading the first processor profile into the processor during a first startup operation of the processor; and
loading the second processor profile into the processor during a second startup operation of the processor.

15. The method of claim 14 comprising:
providing, by the processor, the read address when loading the first processor profile into the processor; and
providing, by the processor, the read address when loading the second processor profile into the processor, wherein the read address provided by the processor is outside the memory range of the target processor profile.
